(19) United States
(12) Patent Application Publication
(10) Pub. No.: US 2018/0104940 A1
(43) Pub. Date: Apr. 19, 2018

(54) CROSSLINKED POLYMER STRUCTURE AND USE FOR SAME

(71) Applicant: NATIONAL INSTITUTE OF ADVANCED INDUSTRIAL SCIENCE AND TECHNOLOGY, Tokyo (JP)

(72) Inventors: Kimio SUMARU, Tsukuba-shi (JP); Toshiyuki TAKAGI, Tsukuba-shi (JP); Kana MORISHITA, Tsukuba-shi (JP); Toshiyuki KANAMORI, Tsukuba-shi (JP)

(21) Appl. No.: 15/565,987

(22) PCT Filed: Apr. 15, 2016
(86) PCT No.: PCT/JP2016/062099

§ 371 Date: Oct. 12, 2017

(30) Foreign Application Priority Data
Apr. 17, 2015 (JP) 2015-085322

(51) Int. Cl. B32B 27/16; C08L 101/06; G03F 7/095

(52) U.S. Cl. CPC B32B 27/16; B32B 2255/10; G03F 7/095; C08L 101/06

(57) ABSTRACT

A method for producing a structure composed of crosslinked polymer, including laminating a photo-dissoluble polymer layer on a substrate; laminating a layer containing a crosslinkable polymer on the photo-dissoluble polymer layer; irradiating the layer containing the crosslinkable polymer with light in a patternwise manner under crosslinking conditions to crosslink the crosslinkable polymer in a patternwise manner to obtain a crosslinked polymer sheet; washing and removing a uncrosslinked crosslinkable polymer to obtain a patterned crosslinked polymer sheet; and irradiating the photo-dissoluble polymer layer with light in a patternwise manner under dissolution conditions to dissolve the photo-dissoluble polymer layer in a patternwise manner, and peeling the crosslinked polymer sheet in a patternwise manner from the substrate.

### TECHNICAL FIELD

The present invention relates to a structure composed of crosslinked polymer and use thereof. More specifically, the present invention relates to a method for producing a structure composed of crosslinked polymer, a laminate for producing a structure composed of crosslinked polymer, a structure composed of crosslinked polymer, a structure composed of crosslinked polymer for cell culture, a cell culture method, a method for producing a cell mass, and a cell mass. Priority is claimed on Japanese Patent Application No. 2015-085322, filed on Apr. 17, 2015, the content of which is incorporated herein by reference.

### BACKGROUND ART

Applications of materials having a microstructure on the surface thereof have been actively studied in various fields including biotechnology and medical care. Particularly, in microfluidic systems, devices, and the like handling cells or the like, attention has been paid to a μm-scale structure forming technique. For example, Patent Document 1 discloses a micro-device for a cellular tissue body, including a cell holding chamber for holding cells, in which the cell holding chamber has a base including at least one tissue body-forming region, an inlet port for charging a culture fluid into the cell holding chamber and an outlet port for discharging the culture fluid from the cell holding chamber; and the tissue body-forming region includes one first region exhibiting cell adhesiveness and a second region surrounding the first region and exhibiting lower cell adhesiveness than that of the first region, and has an area of 100 to 1×10⁶ μm².

### CITATION LIST

### Patent literature

[Patent Document 1] Japanese Patent No. 4033265

### SUMMARY OF INVENTION

### Technical Problem

With such a background, development of a microstruture forming technique is expected. Therefore, it is an object of the present invention to provide a novel microstructure forming technique. More specifically, the object of the present invention is to provide a method for producing a structure composed of crosslinked polymer, a laminate for producing a structure composed of crosslinked polymer, a structure composed of crosslinked polymer, a structure composed of crosslinked polymer for cell culture, a cell culture method, a method for producing a cell mass, and a cell mass.

### Solution to Problem

The present invention includes the following aspects.

(1) A method for producing a structure composed of crosslinked polymer, including: a step (a) of laminating a photo-dissoluble polymer layer on a substrate; a step (b) of laminating a layer containing a crosslinkable polymer on the photo-dissoluble polymer layer; a step (e) of irradiating the layer containing the crosslinkable polymer with light in a patternwise manner under crosslinking conditions to crosslink the crosslinkable polymer in a patternwise manner to obtain a crosslinked polymer sheet; a step (d) of washing and removing a uncrosslinked crosslinkable polymer to obtain a patterned crosslinked polymer sheet; and a step (e) of irradiating the photo-dissoluble polymer layer with light in a patternwise manner under dissolution conditions to dissolve the photo-dissoluble polymer layer in a patternwise manner, and peeling the crosslinked polymer sheet in a patternwise manner from the substrate.

(2) The method for producing the structure composed of crosslinked polymer according to (1), further including a step (f) of breaking and removing the crosslinked polymer sheet peeled in a patternwise manner from the substrate.

(3) The method for producing the structure composed of crosslinked polymer according to (1) or (2), in which the crosslinkable polymer is a compound having a plurality of hydroxyl groups and having a weight-average molecular weight of 2,000 or more.

(4) The method for producing the structure composed of crosslinked polymer according to any one of (1) to (3), in which the crosslinkable polymer is water-soluble.

(5) The method for producing the structure composed of crosslinked polymer according to any one of (1) to (4), in which the crosslinkable polymer is a polysaccharide or a derivative thereof.

(6) A laminate for producing a structure composed of crosslinked polymer, including: a substrate; a photo-dissoluble polymer layer laminated on the substrate; and a layer containing a crosslinkable polymer laminated on the photo-dissoluble polymer layer.

(7) A structure composed of crosslinked polymer, including: a substrate; and a crosslinked polymer sheet provided on the substrate, in which the substrate and the crosslinked polymer sheet have an adhesive region where the substrate and the crosslinked polymer sheet are adhered, and a non-adhesive region where the substrate and the crosslinked polymer sheet are not adhered, in a planar view, the adhesive region of the substrate is closed to surround the periphery of the non-adhesive region of the substrate, and the non-adhesive region of the crosslinked polymer sheet is provided with at least one through-hole.

(8) A structure composed of crosslinked polymer for cell culture, including: a substrate; and a cell adhesivable portion and a non-cell adhesivable portion provided in a patternwise manner on the substrate, in which the substrate is exposed in the ceil adhesivable portion, and the non-cell adhesivable portion is made of a crosslinked polymer sheet adhered on the substrate.

(9) The structure composed of crosslinked polymer for cell culture according to (8), in which the cell adhesivable portion and the non-cell adhesivable portion are linearly arranged in parallel with each other.

(10) The structure composed of crosslinked polymer for cell culture according to (8), in which the cell adhesivable portion has a plurality of island-like portions and connecting portions for connecting together the plurality of the island-like portions.

(11) The structure composed of crosslinked polymer for cell culture according to (10), in which all of the island-like portions have substantially the same area.

(12) A cell culturing method for uniformly culturing cells, including: a step of culturing cells on the surface of the structure composed of crosslinked polymer for cell culture according to (11), with the cells being adhered to the plurality of the island-like portions.

(13) A method for producing a cell mass, including: a step of culturing cells on the surface of the structure composed of crosslinked polymer for cell culture according to (11); and a step of detaching the cells to obtain substantially the same number of cell masses as the number of the island-like portions consisting of the cells being adhered to the plurality of the island-like portions.

(14) A cell mass obtained by the production method according to (13).

### Advantageous Effects of Invention

According to the present invention, it is possible to provide a novel microstructure forming technique. More specifically, the present invention is capable of providing a method for producing a structure composed of crosslinked polymer, a laminate for producing a structure composed of crosslinked polymer, a structure composed of crosslinked polymer, a structure composed of crosslinked polymer for cell culture, a cell culture method, a method for producing a cell mass, and a cell mass.

### BRIEF DESCRIPTION OF DRAWINGS

FIG. 1A is a confocal laser scanning micrograph showing a structure composed of crosslinked polymer produced in Example 2.

FIG. 1B is a confocal laser scanning micrograph showing a structure composed of crosslinked polymer produced in Example 2.

FIG. 1C is a confocal laser scanning micrograph showing a structure composed of crosslinked polymer produced in Example 2.

FIG. 1D is a confocal laser scanning micrograph showing a structure composed of crosslinked polymer produced in Example 2.

FIG. 1E is a confocal laser scanning micrograph showing a structure composed of crosslinked polymer produced in Example 2.

FIG. 2 is an optical micrograph showing a structure composed of crosslinked polymer produced in Example 2.

FIGS. 3(a) to 3(f) are diagrams showing a method for producing a structure composed of crosslinked polymer.

FIG. 4 is an optical micrograph showing the results of Example 3.

FIG. 5A is an optical micrograph showing the results of Example 4.

FIG. 5B is an optical micrograph showing the results of Example 4.

FIG. 6 is an optical micrograph of MDCK cells cultured in Example 5.

FIG. 7A is an optical micrograph of NIH/3T3 cells cultured in Example 5.

FIG. 7B is an optical micrograph of NIH/3T3 cells cultured in Example 5.

FIG. 8 is an optical micrograph of human iPS cells cultured in Example 5.

### DESCRIPTION OF EMBODIMENTS

Hereinafter, embodiments of the present invention will be described in detail with reference to the accompanying drawings as needed. The dimensions in the drawings are partly exaggerated for explanation purposes and do not always correspond to actual ratios of dimensions.

### Method for Producing Structure Composed of Crosslinked Polymer

### First Embodiment

In one embodiment, the present invention provides a method for producing a structure composed of crosslinked polymer, including a step (a) of laminating a photo-dissoluble polymer layer on a substrate; a step (b) of laminating a layer containing a crosslinkable polymer on the photo-dissoluble polymer layer; a step (c) of irradiating the layer containing the crosslinkable polymer with light in a patternwise manner under crosslinking conditions to crosslink the crosslinkable polymer in a patternwise manner to obtain a crosslinked polymer sheet; a step (d) of washing and removing a uncrosslinked crosslinkable polymer to obtain a patterned crosslinked polymer sheet; and a step (e) of irradiating the photo-dissoluble polymer layer with light in a patternwise manner under dissolution conditions to dissolve the photo-dissoluble polymer layer in a patternwise mariner, and peeling the crosslinked polymer sheet in a patternwise manner from the substrate.

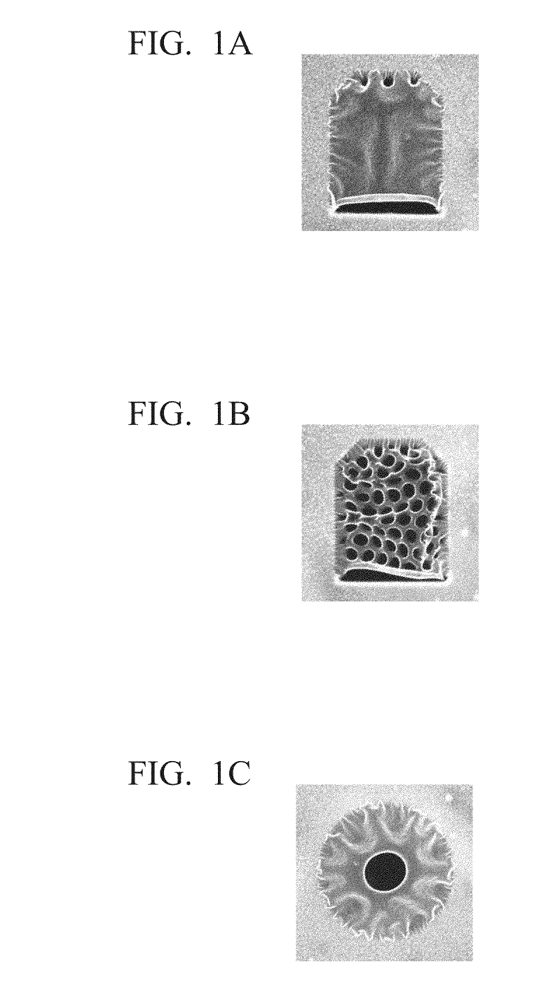

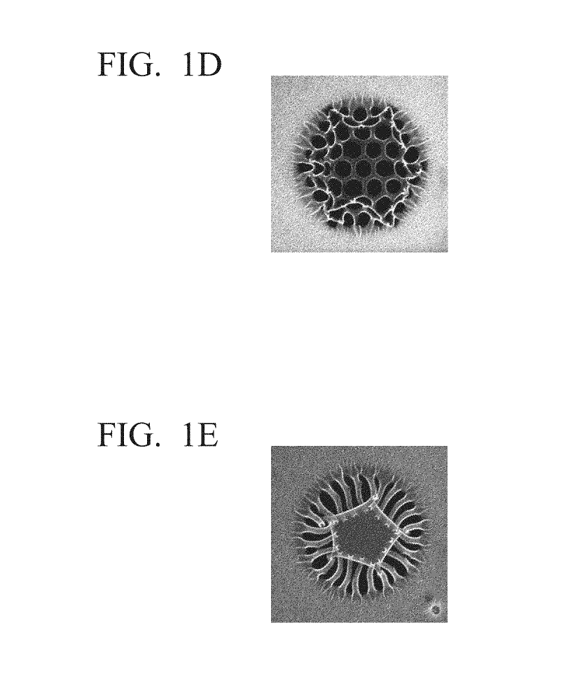

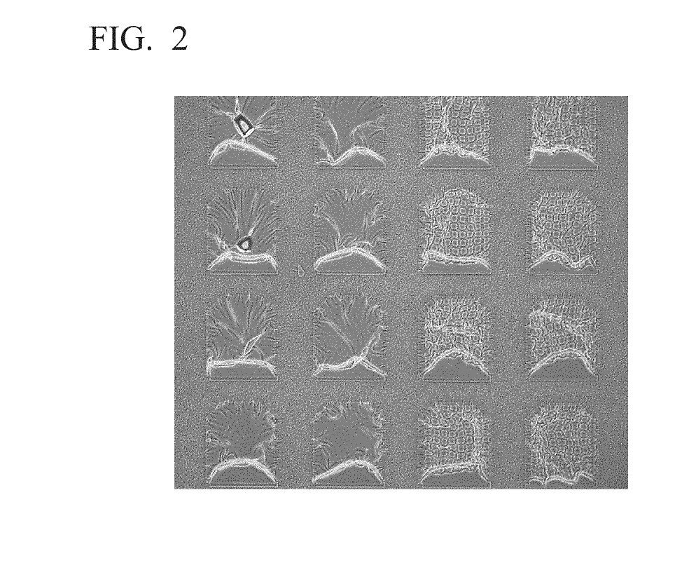

FIGS. 1A to 1B and 2 are photographs showing specific examples of structures composed of crosslinked polymer produced by the production method of the present embodiment. Details of these structures composed of crosslinked polymer will be described later.

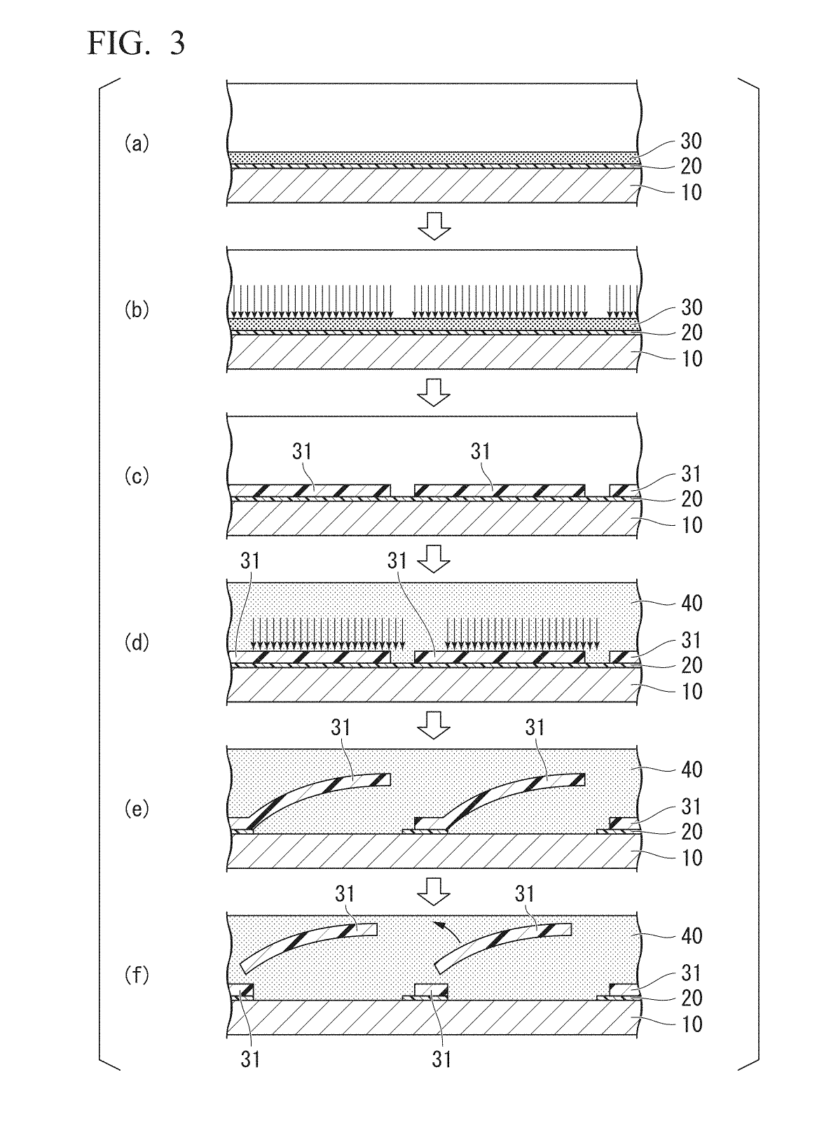

FIGS. 3(a) to 3(e) are diagrams showing the production method of the present embodiment. Hereinafter, the production method of the present embodiment will be described with reference to FIG. 3.

[Step (a)]

In the present step, a photo-dissoluble polymer layer is laminated on a substrate.

(Substrate)

The substrate can be appropriately selected depending on the application of the structure composed of crosslinked polymer. For example, in the case where the structure composed of crosslinked polymer is used for cell culture or the like, which will be described later, it preferably has transmittance to light centered on a wavelength of about 360 to 830 nm so that cells can be observed with an optical microscope, a fluorescence microscope, or the like.

More specific examples of the material for the substrate include glass and resin. Examples of the resin include an ABS resin, a polycarbonate resin, a cycloolefin copolymer (COC), a cycloolefin polymer (COP), an acrylic resin, polyvinyl chloride, a polystyrene resin, a polyolefin resin such as polyethylene, polypropylene, or polymethylpentene, polyvinyl acetate, polyethylene terephthalate (PET), and polyethylene naphthalate (PEN). These resins may contain various additives, or a plurality of resins may be mixed.

The thickness of the substrate is not particularly limited and it may be, for example about 0.1 to 5 mm, for example about 0.3 to 3 mm, or for example about 0.5 to 1 mm.

(Photo-Dissoluble Polymer)

As the photo-dissoluble polymer, for example, a polymer which can be dissolved in a patternwise manner can be used. For example, there is a polymer that decomposes by irradiation with light. Alternatively, there is a polymer in which irradiation with light in a predetermined solvent leads to isomerization of the structure without decomposition and the solubility in the solvent is improved. In the present specification, the term “light” refers to electromagnetic waves such as ultraviolet light, visible light, infrared light, X-rays, and γ-rays.

Examples of the photo-dissoluble polymer include a polymer containing polyethylene glycol as a main chain and having a nitrobenzyl group in the molecule; various crosslinked polymers constituting a positive-type photoresist; a crosslinked polymer having a photocleavable crosslinking point such as an o-nitrobenzyl group or a coumarin group; a polymer having a ketone carbonyl group and a copolymer thereof; a mixed polymer of a ketone copolymer and other synthetic polymers; a copolymer of ethylene and carbon monoxide, or a mixed polymer of such a copolymer and other ethylene polymers; an α-olefin copolymer containing at least one photodegradable metal compound which is a metal compound such as iron, copper, manganese, cobalt, cerium, vanadium, chromium, or nickel; and a polymer containing acetylacetonate copper and dialkyldithiocarbamic acid. The photo-dissoluble polymer can be dissolved, for example, by irradiation with light having a wavelength of 180 to 600 nm in an appropriate solvent such as water, a mixed solvent of ethanol and water, or tetramethylammonium hydroxide.

The method of laminating a photo-dissoluble polymer layer on a substrate may be, for example, a method in which a solution in which the photo-dissoluble polymer is dissolved in an appropriate solvent is applied onto the substrate by dipping, spraying, spin, coating, or the like, and then the solvent is removed. The solvent can be removed by air drying, heating, or the like.

The thickness of the photo-dissoluble polymer layer is not particularly limited and it may be, for example about 2 to 1,000 nm, for example about 5 to 500 nm, or for example, about 10 to 200 nm, in a state where the solvent is removed.

[Step (b)]

In the present step, a layer containing a crosslinkable polymer is laminated on the photo-dissoluble polymer layer.

(Layer Containing Crosslinkable Polymer)

The layer containing a crosslinkable polymer may be a layer of a composition containing a polymer capable of crosslinking upon irradiation with light. Alternatively, the layer containing a crosslinkable polymer may be a layer of a composition containing a crosslinking agent capable of crosslinking by the action of an acid and a crosslinkable polymer. In this case, a polymer layer having a photoacid generating ability may be further laminated on the layer containing a crosslinkable polymer. Details will be provided later. Hereinafter, the term “composition containing a polymer capable of crosslinking upon irradiation with light” or the term “composition containing a crosslinking agent capable of crosslinking by the action of an acid and a crosslinkable polymer” may be referred to as a “pregel composition” in some cases.

(Polymer Capable of Crosslinking Upon Irradiation With Light)

As the polymer capable of crosslinking upon irradiation with light, it is possible to use a polymer having a diazirine group, an azide group, or the like which crosslinks with an amino group or the like upon irradiation with light.

(Crosslinking Agent Capable of Crosslinking by Action of Acid)

The crosslinking agent capable of crosslinking by the action of an acid may be, for example, a crosslinking agent containing an acid labile group capable of forming a carbonium ion in the presence of a strong acid. A more specific example thereof may be tetraalkoxymethyl-substituted glycoluril such as tetramethoxymethyl glycoluril (TMMGU).

(Crosslinkable Polymer)

Examples of the crosslinkable polymer include compounds containing a plurality of hydroxyl groups and having a weight-average molecular weight of, for example 2,000 or more, for example 5,000 to 10,000,000, or for example 10,000 to 1,000,000. In the present specification, the weight-average molecular weight is a value in terms of standard polyethylene glycol measured by a gel permeation chromatography (GPC) method. Further, the crosslinkable polymer may be water-soluble. In the case where the crosslinkable polymer is water-soluble, it can be a hydrogel having permeability of low molecular weight components. In addition, the crosslinkable polymer may be a polysaccharide or a derivative thereof.

Examples of the polysaccharide or the derivative thereof include ethylcellulose, methylcellulose, hydroxypropylcellulose, hydroxymethylcellulose, carboxymethylcellulose, xanthan gum, guar gum, gum arabic, amylose, agarose, agaropectin, arabinan, curdlan, callose, carboxymethyl starch, chitin, chitosan, quince seed gum, glucomannan, gellan gum, tamarind seed gum, dextran, nigeran, hyaluronic acid, pustulan, funoran, pectin, porphyran, laminaran, lichenan, carrageenan, alginic acid, tragacanth gum, arukashigamu, locust bean gum, xanthan gum, rhamsan gum, agar, and microfibrillated cellulose.

A more specific example of the crosslinkable polymer may be a crosslinkable polymer capable of forming a hydrogel in water, examples thereof include partially saponified polyvinyl acetate, polyvinyl alcohol, hydroxyalkyl cellulose such as hydroxypropylcellulose, and a vinyl pyrrolidone-vinyl alcohol copolymer.

(Pregel Composition)

The pregel composition may be, for example, a composition in which the above-described polymer capable of crosslinking-upon irradiation with light and, as necessary, an appropriate additive are dissolved or dispersed in a solvent, or a composition in which a crosslinking agent capable of crosslinking by the action of an acid, a crosslinkable polymer and, as necessary, an appropriate additive are dissolved or dispersed in a solvent. Examples of the solvent include methanol, ethanol, propanol, and butanol. Examples of the additive include sulfuric acid, trifluoroacetic acid, and alkyl sulfuric acid.

In the case where a composition containing a polymer capable of crosslinking upon irradiation with light is used as the pregel composition, the method of laminating the layer of the pregel composition on the photo-dissoluble polymer layer is not particularly limited. For example, the pregel composition may be applied onto the photo-dissoluble polymer layer by dipping, spraying, spin coating, doctor blade coating, lip coating, or the like. After applying the pregel composition, it is preferable to remove the solvent in the pregel composition. The solvent can be removed by air drying, heating, or the like.

The thickness of the layer of the pregel composition is not particularly limited, and it may be, for example about 0.01 to 100 μm, for example about 0.03 to 30 μm, or for example, about 0.1 to 10 μm, in a state where the solvent is removed.

On the other hand, in the case where a composition containing a crosslinking agent capable of crosslinking by the action of an acid and a crosslinkable polymer is used as the pregel composition, a polymer layer having a photoacid generating ability may be further laminated on the layer containing a crosslinkable polymer. This makes it possible for the acid generated by irradiating the polymer layer having a photoacid generating ability with light to change the crosslinking agent capable of crosslinking by the action of an acid into a state capable of crosslinking, so that it becomes possible to crosslink the crosslinkable polymer. That is, by laminating a polymer layer having a photoacid generating ability on a layer containing a crosslinkable polymer, it is possible to crosslink the crosslinkable polymer in patternwise manner through patternwise light irradiation. Here, the photon-dissoluble polymer layer may have a photoacid generating ability. That is, a photo-dissoluble polymer layer having a photoacid generating ability may be used as the photo-dissoluble polymer layer.

(Polymer Having Photoacid Generating Ability)

As the polymer having a photoacid generating ability, for example, a polymer capable of generating an acid in a patternwise manner can be used. For example, a polymer capable of generating an acid upon irradiation with light can be mentioned. Examples of such a polymer include those having a structure consisting of a chromophore absorbs light and an acid precursor that becomes an acidic substance after decomposition.

As the polymer having a photoacid generating ability, for example, a polymer containing a photoacid generator can be used.

Examples of the photoacid generator include sulfonic acid derivatives, carboxylic acid esters, and onium salts.

Examples of the sulfonic acid derivatives include a naphthalene imide-based sulfonic acid derivative and a thioxanthone-based sulfonic acid derivative. The naphthalene imide-based sulfonic acid derivative may be, for example, sulfonic acid 1,8-naphthalimide. The thioxanthone-based sulfonic acid derivative may be, for example, sulfonic acid 1,3,6-trioxo-3,6-dihydro-1H-11-thia-azacyclopenta[a]anthracen-2-yl ester. Examples of other sulfonic acid derivatives include disulfones, disulfonyldiazomethanes, disulfonylmethanes, sulfonylbenzoylmethanes, imide sulfonates, and benzoin sulfonates.

Examples of the carboxylic acid esters include 1,8-naphthalenedicarboxylic acid imide methylsulfonate and 1,8-naphthalenedicarboxylic acid imide tosylsulfonate.

Examples of the onium salts include sulfonium salts and iodonium salts having an anion such as tetrafluoroborate (BF₄⁻), hexafluorophosphate (PF₆⁻), or hexafluoroantimonate (SbF₆⁻).

Examples of the polymer include a polystyrene-based resin and a (meth)acrylic resin. In the present specification, the (meth)acrylic resin refers to an acrylic resin and a methacrylie resin.

The method of laminating a polymer layer having a photoacid generating ability on a substrate is the same as the above-described method of laminating a photo-dissoluble polymer layer on a substrate.

The thickness of the polymer layer having a photoacid generating ability is not particularly limited and it may be, for example about 2 to 1,000 nm, for example about 5 to 500 nm, or for example, about 10 to 200 nm, in a state where the solvent is removed.

(Photo-Dissoluble Polymer Having Photoacid Generating Ability)

A photo-dissoluble polymer having a photoacid generating ability may be used in place of the photo-dissoluble polymer and the polymer having a photoacid generating ability described above. More specific examples of the photo-dissoluble polymer having a photoacid generating ability include polymethyl methacrylate having a photoacid generating group in the side chain (hereinafter, sometimes referred to as “pPAGMMA”), polymethyl methacrylate, and poly(N-alkyl acrylamide). Examples of the photoacid generating group include a sulfonate derivative such as naphthalene imide-based sulfonic acid or thioxanthone-based sulfonic acid, a sulfonyl compound, and an onium compound.

The pPAGMMA is capable of generating protons upon irradiation with light having a wavelength of 320 to 480 nm in the atmosphere or the like environment. Further, the pPAGMMA may be dissolved in an appropriate solvent such as ethanol containing 20 mass % of water, upon irradiation with light having a wavelength of 320 to 480 nm.

The method of laminating a photo-dissoluble polymer layer having a photoacid generating ability on a substrate is the same as the above-described method of laminating a photo-dissoluble polymer layer on a substrate.

The thickness of the photo-dissoluble polymer layer having a photoacid generating ability is not particularly limited and it may be, for example about 2 to 1,000 nm, for example about 5 to 500 nm, or for example about 10 to 200 nm, in a state where the solvent is removed.

In the case where a composition containing a crosslinking agent capable of crosslinking by the action of an acid and a crosslinkable polymer is used as the pregel composition, the method of applying the pregel composition on the polymer layer having a photoacid generating ability or the photo-dissoluble polymer layer having a photoacid generating ability is not particularly limited. For example, there is a method in which the pregel composition is applied onto the polymer layer having a photoacid generating ability or the photo-dissoluble polymer layer having a photoacid generating ability by dipping, spraying, spin coating, doctor blade coating, lip coating, or the like. After applying the pregel composition, it is preferable to remove the solvent in the pregel composition. The solvent can be removed by air drying, heating, or the like.

The thickness of the layer of the pregel composition is the same as in the case of the above-described composition containing a polymer capable of crosslinking upon irradiation with light.

FIG. 3(a) is a diagram showing a state in which a photo-dissoluble polymer layer 20 having a photoacid generating ability is laminated on a substrate 10 and a pregel composition (a composition containing a crosslinking agent capable of crosslinking by the action of an acid and a crosslinkable polymer) 30 is further applied thereon, as an example.

[Step (c)]

In the present step, the layer containing a crosslinkable polymer is irradiated with light in a patternwise manner under crosslinking conditions to crosslink the crosslinkable polymer in a patternwise manner, thereby obtaining a crosslinked polymer sheet.

(Light Irradiation Under Crosslinking Conditions)

In the case where the above-described composition containing a polymer capable of crosslinking upon irradiation with light is used as the pregel composition, the term “under crosslinking conditions” refers to appropriate conditions capable of crosslinking the polymer used. The crosslinkable polymer in the pregel composition is crosslinked upon irradiation with light.

As a result, the pregel composition forms a crosslinked polymer sheet in the portion irradiated with light.

In the case where the above-described composition containing a crosslinking agent capable of crosslinking by the action of an acid and a crosslinkable polymer is used as the pregel composition, the term “under crosslinking conditions” refers to appropriate conditions corresponding to the polymer having a photoacid generating ability or the photo-dissoluble polymer having a photoacid generating ability used. For example, in the case where the above-described pPAGMMA is used as the photo-dissoluble polymer having a photoacid generating ability, the crosslinking conditions may be, for example, conditions such as irradiating 3 J/cm² of light having a wavelength of 436 nm in the air. Light irradiation in a patternwise manner may be carried out by a general photolithography technique.

Irradiation of light leads to generation of an acid in the polymer layer having a photoacid generating ability or the photo-dissoluble polymer layer having a photoacid generating ability, whereby the crosslinkable polymer is crosslinked by the crosslinking agent in the pregel composition. As a result, the pregel composition forms a crosslinked polymer sheet in the portion irradiated with light. After light irradiation, heating or the like may be carried out to accelerate the crosslinking of the crosslinkable polymer.

FIG 3(b) is a diagram showing a state in which the photo-dissoluble polymer layer 20 having a photoacid generating ability is irradiated with light in a patternwise manner to crosslink the crosslinkable polymer.

[Step (d)]

In the present step, the crosslinkable polymer which has not been crosslinked is washed and removed to obtain a patterned crosslinked polymer sheet. For washing, an appropriate washing liquid can be used. The washing liquid may be, for example, ethanol containing water. FIG. 3(c) is a diagram showing a state in which the pregel composition of the portion not irradiated with light is washed and removed. A crosslinked polymer sheet 31 is formed in the portion irradiated with light.

[Step (e)]

In the present step, the photo-dissoluble polymer layer or the photo-dissoluble polymer layer having a photoacid generating ability is irradiated with light in a patternwise manner under dissolution conditions to dissolve the photo-dissoluble polymer layer or the photo-dissoluble polymer layer having a photoacid generating ability in a patternwise manner, and the crosslinked polymer sheet is peeled in a patternwise manner from the substrate.

(Light Irradiation Under Dissolution Conditions)

The dissolution conditions refer to appropriate conditions corresponding to the photo-dissoluble polymer or the photo-dissoluble polymer having a photoacid generating ability used. For example, in the case where the above-described pPAGMMA is used as the photo-dissoluble polymer having a photoacid generating ability, the dissolution conditions may be, for example, conditions such as irradiating 10 J/cm² of light having a wavelength of 436 nm in a mixed solvent of ethanol and water. Light irradiation in a patternwise manner may be carried out by a general photolithography technique.

Irradiation of light leads to dissolution of the photo-dissoluble polymer or the photo-dissoluble polymer having a photoacid generating ability. As a result, in the portion irradiated with light, the crosslinked polymer sheet described above is peeled from the substrate. FIG. 3(d) is a diagram showing a state in which the photo-dissoluble polymer layer 20 having a photoacid generating ability is irradiated with light in a patternwise manner in a suitable solvent 40 to dissolve the photo-dissoluble polymer having a photoacid generating ability. FIG. 3(e) is a diagram showing a state in which the crosslinked polymer sheet 31 is peeled off in a patternwise manner from the substrate 10, as a result of dissolution of the photo-dissoluble polymer having a photoacid generating ability. In the example of FIG. 3(e), a pocket-like structure composed of crosslinked polymer is formed. The pocket-like structure composed of crosslinked polymer will be described later.

According to the production method of the present embodiment, by appropriately setting a pattern for crosslinking the pregel composition and a pattern for dissolving the photo-dissoluble polymer or the photo-dissoluble polymer having a photoacid generating ability, structures composed of crosslinked polymer of various shapes can be produced. The time from selection of the pattern of light irradiation to completion of the structure composed of crosslinked polymer is only a few minutes.

Since the production method of the present embodiment is extremely simple, it is possible to provide a powerful experiment examination means at the research site of cell engineering, or the like, where the importance of a pattern culture system has been widely recognized.

### Second Embodiment

In one embodiment, the present invention provides a method for producing a structure composed of crosslinked polymer further including a step (f) of breaking and removing the crosslinked polymer sheet peeled off in a patternwise manner from the substrate, in addition to the steps (a) to (e) in the above-described first embodiment. The breakage and removal of the crosslinked polymer sheet may be carried out, for example, by applying a physical force to the crosslinked polymer sheet.

[Step (f)]

in the present step, the crosslinked polymer sheet peeled off in a patternwise manner from the substrate is broken and removed in a patternwise manner.

The method for applying a physical force may be, for example, strongly spraying a liquid such as water with an automatic pipetter or the like which is used in cell culture.

FIG. 3(f) is a diagram showing a manner of breaking and removing the crosslinked polymer sheet 31 peeled off in a patternwise manner from the substrate. For example, as shown by the arrow in FIG. 3(f) the crosslinked polymer sheet 31 peeled off from the substrate is broken and removed by spraying a liquid 40 on the pocket-like structure composed of crosslinked polymer in a suitable liquid 40.

According to the production method of the present embodiment, a region where the substrate is substantially exposed and a region where the polymer sheet is adhered on the substrate can be formed in a patternwise manner. Here, the region where the substrate is substantially exposed means that a state in which the photo-dissoluble polymer layer or the photo-dissoluble polymer layer having a photoacid generating ability is not completely dissolved but remains slightly in the production method of the present embodiment is also included in the region where the substrate is exposed.

The structure composed of crosslinked polymer produced by the production method of the present embodiment can be used, for example, as a polymer structure for cell culture. The structure composed of crosslinked polymer for cell culture will be described later.

### Laminate for Producing Structure Composed of Crosslinked Polymer

In one embodiment, the present invention provides a laminate for producing a structure composed of crosslinked polymer, including a substrate, a photo-dissoluble polymer layer laminated on the substrate, and a layer containing a crosslinkable polymer laminated on the photo-dissoluble polymer layer.

The laminate for producing a structure composed of crosslinked polymer of the present embodiment may be one including a substrate, a photo-dissoluble polymer layer laminated on the substrate, and a polymer layer having a photoacid generating ability laminated on the photo-dissoluble polymer layer, or a photo-dissoluble polymer layer having a photoacid generating ability laminated on the substrate; and a composition containing a crosslinking agent capable of crosslinking by the action of an acid and a crosslinkable polymer, coated on the polymer layer having a photoacid generating ability or the photo-dissoluble polymer layer having a photoacid generating ability.

It is possible to produce various structures composed of crosslinked polymer by carrying out the steps (c) to (e) of the above-described method for producing a structure composed of crosslinked polymer on the laminate for producing a structure composed of crosslinked polymer of the present embodiment.

In the laminate for producing a structure composed of crosslinked polymer of the present embodiment, as for the substrate, the photo-dissoluble polymer, the crosslinkable polymer, the composition (pregel composition) containing a polymer capable of crosslinking upon irradiation with light, the polymer having a photoacid generating ability, the photo-dissoluble polymer having a photoacid generating ability, the crosslinking agent capable of crosslinking by the action of an acid, and the composition (pregel composition) containing a crosslinking agent capable of crosslinking by the action of an acid and a crosslinkable polymer, the same ones as those described above can be used.

### Structure Composed of Crosslinked Polymer

### First Embodiment

In one embodiment, the present invention provides a structure composed of crosslinked polymer including a substrate and a crosslinked polymer sheet provided on the substrate, in which the substrate and the crosslinked polymer sheet have an adhesive region where the substrate and the crosslinked polymer sheet are adhered, and a non-adhesive region where the substrate and the crosslinked polymer sheet are not adhered, in a planar view, the adhesive region of the substrate is closed to surround the periphery of the non-adhesive region of the substrate, and the non-adhesive region of the crosslinked polymer sheet provided with at least one through-hole. In the present specification, the term “planar view” refers to a state in which the substrate is viewed from a direction perpendicular to the substrate.

The structure composed of crosslinked polymer of the present embodiment can be produced, for example, by the method for producing a structure composed of crosslinked polymer according to the above-described first embodiment. Therefore, the substrate, the photo-dissoluble polymer, the crosslinkable polymer, the composition (pregel composition) containing a polymer capable of crosslinking upon irradiation with light, the polymer having a photoacid generating ability, the photo-dissoluble polymer having a photoacid generating ability, the crosslinking agent capable of crosslinking by the action of an acid, and the composition (pregel composition) containing a crosslinking agent capable of crosslinking by the action of an acid and a crosslinkable polymer, which are used for producing the structure composed of crosslinked polymer of the present embodiment, are the same as those used in the method for producing a structure composed of crosslinked polymer according to the above-described first embodiment.

In the structure composed of crosslinked polymer of the present embodiment, the adhesive region to which the substrate and the polymer sheet are adhered refers to a region where the crosslinked polymer sheet was not peeled off from the substrate in the step (e), in the region where the pregel composition was crosslinked to form a crosslinked polymer sheet in step (c) of the method for producing a structure composed of crosslinked polymer according to the above-described first embodiment.

Here, the adhesive region of the substrate refers to the above-described adhesive region in the substrate, and the adhesive region of the crosslinked polymer sheet refers to the above-described adhesive region in the crosslinked polymer sheet.

In addition, the non-adhesive region refers to a region where the crosslinked polymer sheet was peeled off from the substrate in the step (e), in the region where the pregel composition was crosslinked to form a crosslinked polymer sheet in the step (c) of the method for producing a structure composed of crosslinked polymer according to the above-described first embodiment.

Here, the non-adhesive region of the substrate refers to the above-described non-adhesive region in the substrate (region where the substrate is substantially exposed), and the non-adhesive region of the crosslinked polymer sheet refers to the above-described non-adhesive region in the crosslinked polymer sheet (region of the crosslinked polymer sheet which is peeled from the substrate).

In the structure composed of crosslinked polymer of the present embodiment, in a planar view, the adhesive region of the substrate is closed to surround the periphery of the non-adhesive region of the substrate. In addition, at least one through-hole exists in the non-adhesive region of the crosslinked polymer sheet. As a result, the structure composed of crosslinked polymer of the present embodiment forms a pocket-like structure (bag-like structure).

Specific examples of the structure composed of crosslinked polymer of the present embodiment include the structures shown in FIGS. 1(a) to 1(e) and 2.

For example, in the structure shown in FIGS. 1A, 1B and 2, it can be said that the lower through-hole (opening) is the entrance of the pocket. Further, in the structures shown in FIGS. 1C, 1D and 1E, it can be said that the front side of the substrate or the back side of the substrate is the entrance of the pocket.

The pocket-like structure composed of crosslinked polymer may have any type of opening. The crosslinked polymer sheet constituting the pocket-like structure composed of crosslinked polymer may have one or a plurality of through-holes in addition to the opening of the pocket. For example, in the structure shown in FIG. 1A, three through-holes are formed on the upper side of the structure. In the structures shown in FIGS. 1B and 1D and in the right half of FIG. 2 (the third and fourth rows from the left), a plurality of through-holes are formed in the crosslinked polymer sheet to form a mesh-like structure. Also in the structure shown in FIG. 1E, a plurality of through-holes are formed in the crosslinked polymer sheet.

(Application of Structure Composed of Crosslinked Polymer of First Embodiment)

«Cell Culture»

While utilization of human iPS-derived cells is being studied seriously, techniques for culturing cells adhered on a culture substrate in a flowing culture fluid (perfusion culture) have been extensively investigated, particularly in the field of pharmaceutical assay or the like.

In perfusion culture in the field of pharmaceutical assay or the like, it is important that cells are immobilized on a substrate without floating, so that the cells can be observed and evaluated at any time. In many cases, anchorage-dependent cells are previously adhered on the substrate and then the culture fluid is allowed to flow. However, since it is impossible to allow the culture fluid to flow for the time until the cells are adhered on the substrate, depletion of oxygen and nutrients may be a problem.

In addition, in order to carry out perfusion culture of floating cells and cell masses having no adhesiveness on a substrate that can be monitored at any time, it is necessary to have a mechanism for immobilizing them. Application of a material having a minute structure on the surface has been studied as a technique for keeping a floating micro object at a predetermined position in a flowing liquid. For example, using a columnar structure disposed in a flow path has been studied.

However, in the case where floating cells or cell masses having no adhesiveness are held in a predetermined region by means of a columnar structure disposed in the flow path, there may be a case where the flow of the culture fluid is deteriorated due to the cells blocked by the columnar structure. As a result, the original purpose of perfusion culture to spread a fresh culture fluid to cells cannot be achieved.

On the other hand, by capturing floating cells or cell masses having no adhesiveness inside the above-described pocket-like structure composed of crosslinked polymer, it is possible to keep the cells in a predetermined region. This makes it possible to flow a culture medium immediately after capturing the cells inside the pocket structure. At that time, the culture fluid can flow freely above the pocket structure, and there is no disturbance of the overall flow. In addition, since the crosslinked polymer sheet constituting the pocket is thin and transparent, it does not seriously affect the observation of the cells inside. In addition, since the pocket portion can be broken by strongly spraying the culture fluid to the pocket structure, the cells can be easily recovered from the inside of the pocket structure.

Further, by providing a plurality of through-holes in the crosslinked polymer sheet constituting the pocket, an object having a size larger than the size of the through-hole is captured while an object or fluid having a size equal to or smaller than the size of the through-hole can pass through the interior of the pocket. Therefore, it is also possible to selectively capture an object of a predetermined size and efficiently separate it from an object having a size equal to or smaller than a predetermined size. In so doing, the fluid can be supplied to the captured object surface without its flow being disturbed by the pocket structure. That is, a useful cell perfusion culture means can be provided by capturing floating cells or cell masses having no adhesiveness as the above-described object in the above-described pocket-like structure composed of crosslinked polymer.

In the case where the structure composed of crosslinked polymer of the first embodiment is used for cell culture, the area of the non-adhesive region of the substrate may be, for example 10 to 100,000,000 μm², for example 50 to 10,000,000 μm², or for example, 100 to 1,000,000 μm².

«Valve»

Also, the pocket-like structure composed of crosslinked polymer is inflated in response to the flow of a fluid from the inlet direction of the pocket, thus blocking the flow of the fluid, while it is deflated in response to the flow of the fluid in the opposite direction, thus not blocking the flow of the fluid. Therefore, by arranging the pocket-like structure composed of crosslinked polymer in the flow path, it is possible to form a flow path in which the flow path resistance varies depending on the direction of the fluid flow. Thus, the pocket-like structure composed of crosslinked polymer may serve to function as a valve, for example, in a fluidic device.

### Second Embodiment

In one embodiment the present invention provides a structure composed of crosslinked polymer for cell culture, including: a substrate; and a cell adhesivable portion and a non-cell adhesivable portion provided in a patternwise manner on the substrate, in which the substrate is exposed in the cell adhesivable portion, and the non-cell adhesivable portion is made of a crosslinked polymer sheet adhered on the substrate. The structure composed of crosslinked polymer for cell culture of the present embodiment can also be said to be a cell culture substrate.

The structure composed of crosslinked polymer of the present embodiment can be produced, for example, by the method for producing a structure composed of crosslinked polymer according to the above-described second embodiment. Therefore, the substrate, the photo-dissoluble polymer, the crosslinkable polymer, the composition (pregel composition) containing a polymer capable of crosslinking upon irradiation with light, the polymer having a photoacid generating ability, the photo-dissoluble polymer having a photoacid generating ability, the crosslinking agent capable of crosslinking by the action of an acid, and the composition pregel composition) containing a crosslinking agent capable of crosslinking by the action of an acid and a crosslinkable polymer, which are used for producing the structure composed of crosslinked polymer of the present embodiment, are the same as those used in the method for producing a structure composed of crosslinked polymer according to the above-described second embodiment.

In the structure composed of crosslinked polymer of the present embodiment, cells can adhere to the cell adhesivable portion. On the other hand, the non-cell adhesivable portion has a strong cell adhesion inhibitory property, so that cell adhesion is strongly inhibited. By using the structure composed of crosslinked polymer of the present embodiment, it is possible to construct a pattern culture system in which cells are adhered in a patternwise manner and cultured.

In the structure composed of crosslinked polymer of the present embodiment, the cell adhesivable portion is a region in which the substrate is substantially exposed. In addition, the non-cell adhesivable portion is a region where the crosslinked polymer sheet is adhered to the substrate. In particular, since a hydrogel made of a neutral hydratable polymer has a strong cell adhesion inhibitory property, it is suitable as a material constituting the non-cell adhesivable portion of the structure composed of crosslinked polymer of the present embodiment.

(Arrangement Example 1 of Cell Adhesivable Portion and Non-Cell Adhesivable Portion)

In the structure composed of crosslinked polymer for cell culture of the present embodiment, the cell adhesivable portion and the non-cell adhesivable portion may be linearly arranged in parallel with each other.

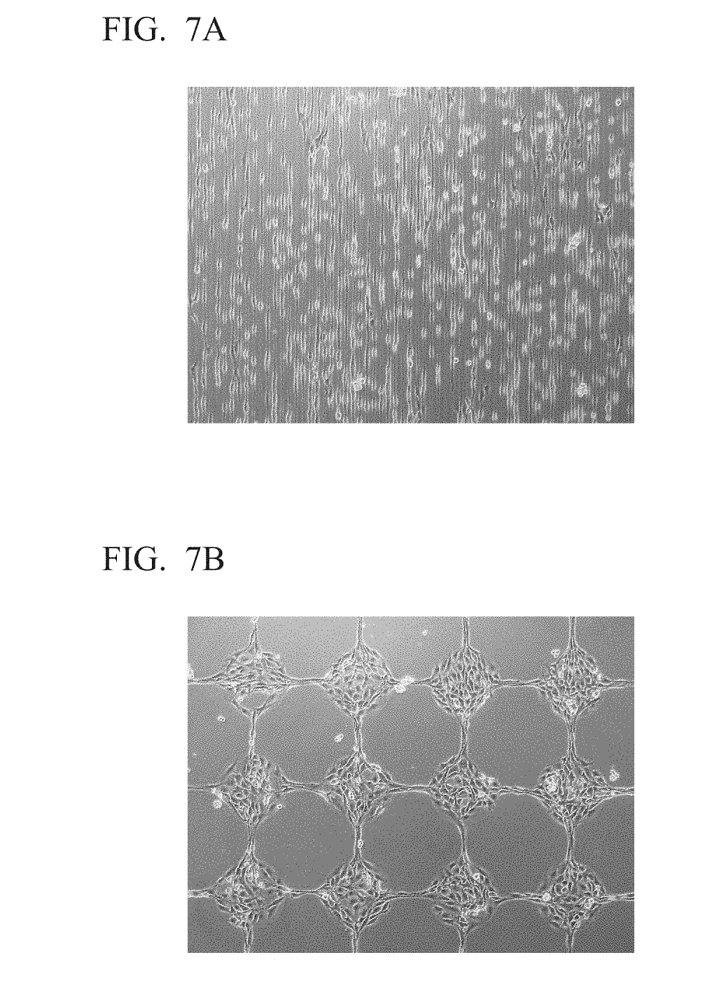

As shown in Examples to be described later, FIG. 7A is a photograph showing the results of culturing cells on a structure composed of crosslinked polymer for cell culture in which a cell adhesivable portion and a non-cell adhesivable portion are linearly arranged in parallel with each other. By arranging the cell adhesivable portion and the non-cell adhesivable portion in this way, cells can be aligned and oriented in parallel.

(Arrangement Example 2 of Cell Adhesivable Portion and Non-Cell Adhesivable Portion)

In the structure composed of crosslinked polymer for cell culture of the present embodiment, the cell adhesivable portion may have a plurality of island-like portions and connecting portions for connecting together the plurality of the island-like portions.

The present inventors have found that, in the case where cells are cultured using a structure composed of crosslinked polymer for cell culture having a plurality of independent island-like cell adhesivable portions, the degree of proliferation of cells in each of the island-like portions tends to be non-uniform.

The present inventors further have found that, in the case where cells are cultured using a structure composed of crosslinked polymer for cell culture in which a pattern shape of a cell adhesivable portion is formed into a shape having a plurality of independent island-like portions and connecting portions for connecting together the island-like portions, the degree of proliferation of cells in each of the island-like portions tends to be uniform.

That is, by using a structure composed of crosslinked polymer for cell culture having a cell adhesivable portion, having a shape having a plurality of island-like portions and connecting portions for connecting together the plurality of the island-like portions, the degree of proliferation of the cells in each of the island-like portions can be made uniform and the cells can be homogeneously cultured.

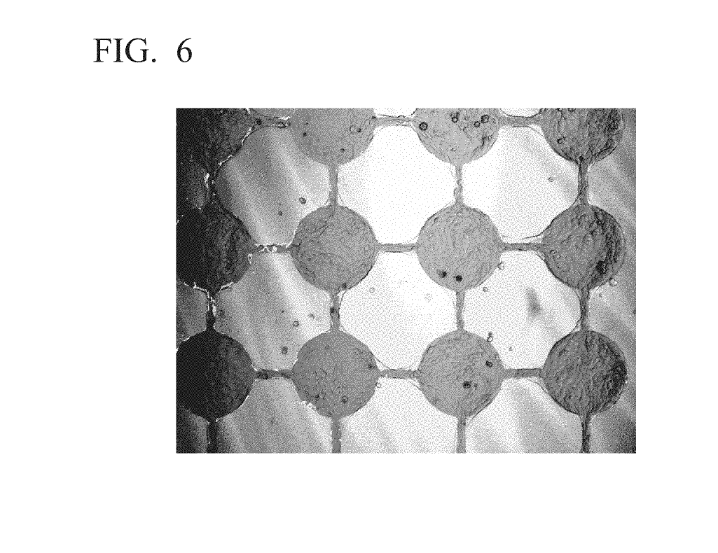

As shown in Examples to be described later, FIGS. 6, 7B, and 8 are photographs showing the results of culturing cells on a structure composed of crosslinked polymer for cell culture in which the cell adhesivable portion has a plurality of island-like portions and connecting portions for connecting together the plurality of the island-like portions. By arranging the cell adhesivable portion and the non-cell adhesivable portion in this way, the degree of proliferation of the cells in each of the island-like portions can be made uniform and the cells can be homogeneously cultured.

In the structure composed of crosslinked polymer for cell culture of the present embodiment, the shape of the island-like portion is not particularly limited, and examples thereof include a circular shape, a rectangular shape, a polygonal shape, and other indefinite shapes. Here, the circular shape includes an elliptical shape. The polygonal shape may be a triangular shape, a quadrangular shape, a pentagonal shape, a hexagonal shape, or the like.

Further, it can be said that the portion of the cell adhesivable portion that is narrow in the top view is the connecting portion and the portion excluding the connecting portion is the island-like portion.

The area per island-like portion may be, for example 200 to 100,000,000 μm², for example 1,000 to 200,000 μm², or for example 5,000 to 50,000 μm².

In addition, in the case where it is intended to produce a cell mass having a uniform size as described below, it is preferable that all of the island-like portions have substantially the same area. Here, the term “substantially the same” is intended to permit variations that are difficult to eliminate in the production process.

### Cell Culture Method and Cells

In one embodiment the present invention provides a cell culture method for uniformly culturing cells, including a step of culturing cells on a surface of a structure composed of crosslinked polymer for cell culture in which a cell adhesivable portion has a plurality of island-like portions and connecting portions for connecting together the plurality of the island-like portions, and all of the island-like portions have substantially the same area, with the cells being adhered to the plurality of the island-like portions.

As described above, the present inventors found that, by culturing cells on the surface of such a structure composed of crosslinked polymer for cell culture, the cells adhered to the plurality of the island-like portions can be uniformly cultured.

In one embodiment, the present invention provides a cell cultured by the cell culture method described above.

The cell of the present embodiment may be distributed together with a structure composed of crosslinked polymer for cell culture in a state of the cell being adhered on the structure composed of crosslinked polymer for cell culture.

### Method For Producing Cell Mass and Cell Mass

In one embodiment, the present invention provides a method for producing a cell mass, including a step of culturing cells on a surface of a structure composed of crosslinked polymer for cell culture in which a cell adhesivable portion has a plurality of island-like portions and connecting portions for connecting together the plurality of the island-like portions, and all of the island-like portions have substantially the same area; and a step of detaching the cells to obtain substantially the same number of cell masses as the number of the island-like portions consisting of the cells adhering to the plurality of the island-like portions. According to the method for producing a cell mass of the present embodiment, it is possible to obtain a cell mass having a uniform size.

Here, the phrase “substantially the same number of cell masses as the number of the island-like portions” is intended to permit there is a case where the number of cell masses completely matched with the number of the island-like portions cannot be obtained due to destruction of a cell mass or the like which cannot be excluded in operations such as detachment of cells.

For example, in research using iPS cells or iPS-derived cells, or in fields utilizing these cells, it is sometimes necessary to prepare a uniform cell mass of these cells. According to the method for producing a cell mass of the present embodiment, it is possible to easily produce a cell mass of iPS cells or the like having a uniform size.

The method for detaching the cells may be, for example, a method of reacting the cells with an enzyme such as trypsin or collagenase, or a method of washing the cells with a buffer solution containing a chelating agent to remove calcium ions necessary for cell adhesion.

In one embodiment, the present invention provides a cell mass cultured by the above-described method for producing a cell mass.

Since the cell mass of the present embodiment exhibits a uniform size, it can be effectively used for, for example, cell assays of pharmaceuticals and chemical products, and research and utilization using iPS cells.

### EXAMPLES

Hereinafter, the present invention will be described in more detail with reference to the following Examples, but the present invention is not limited thereto.

### Example 1

### Formation Of Pocket-Like Structure Composed of Crosslinked Polymer 1

pPAGMMA containing a photoacid generating residue and having a monomer fraction of 2 mol % was used as a photo-dissoluble polymer having a photoacid generating ability. First, a trifluoroethanol solution containing 1 mass % of pPAGMMA was spin-coated on a polystyrene substrate and heated at 85° C. for 1 hour.

Subsequently, a methanol solution containing 5 mass % of partially hydrolyzed polyvinyl acetate, 0.1mass % of tetramethoxymethylglycoluril (hereinafter, sometimes referred to as “TMMGU” ), and 0.005 mass % of sulfuric acid was prepared as a composition containing a crosslinking agent capable of crosslinking by the action of an acid and a crosslinkable polymer. The composition was spin-coated on the substrate and heated at 85° C. for 5 minutes.

This was followed by exposure to light having a wavelength of 436 nm at an irradiation dose of 3 J/cm² along the pattern forming a polymer sheet (gel layer). Subsequently, after heating at 85° C. for 2 hours, development was carried out by washing and removing the unexposed portion with ethanol containing water.

The formed polymer sheet was exposed to light having a wavelength of 436 nm at an irradiation dose of 10 J/cm² in a patternwise manner in ethanol containing 20 weight % of water to dissolve pPAGMMA, and the polymer sheet was locally peeled off from the substrate surface to form a pocket-like structure composed of crosslinked polymer.

### Example 2

### Formation of Pocket-Like Structure Composed of Crosslinked Polymer 2

pPAGMMA containing a photoacid generating residue and having a monomer fraction of 2 mol % was used as a photo-dissoluble polymer having a photoacid generating ability. First, a trifluoroethanol solution containing 1 mass % of pPAGMMA was spin-coated on a polystyrene substrate and heated at 85° C. for 1 hour.

Subsequently, a methanol solution containing 5 mass % of hydroxypropylcellulose, 0.1 mass % of TMMGU, and 0.005 mass % of sulfuric acid was prepared as a composition containing a crosslinking agent capable of crosslinking by the action of an acid and a crosslinkable polymer. The composition was spin-coated on the substrate and heated at 85° C. for 5 minutes.

This was followed by exposure to light having a wavelength of 436 nm at an irradiation dose of 3 J/cm² along the pattern forming a polymer sheet. Subsequently, after heating at 85° C. for 2 hours, development was carried out by washing and removing the unexposed portion with water.

The formed polymer sheet was exposed to light having a wavelength of 436 nm at an irradiation dose of 10 J/cm² in a patternwise manner in ethanol containing 20 weight % of water to dissolve pPAGMMA, and the polymer sheet was locally peeled off from the substrate surface to form a pocket-like structure composed of crosslinked polymer having one or a plurality of through-holes in the peeled area of the polymer sheet.

FIGS. 1A to 1E are photographs showing the results of confocal laser scanning microscopic observation of a pocket-like structure composed of crosslinked polymer formed in the present Example. FIG. 2 is a photograph showing the results of optical microscopic observation of a pocket array in which pocket-like structures composed of crosslinked polymer are arranged in an array, which was formed in the present Example. In the pocket-like structure composed of crosslinked polymer shown in the right half of FIG. 2, a large number of rectangular through-holes are formed in a region where the polymer sheet is peeled off (a region where the pocket is formed) and are in a mesh shape (hereinafter, sometimes referred to as “mesh-like pocket structure”).

### Example 3

### Cell Culture Using Pocket-Like Structure Composed of Cross Linked Polymer

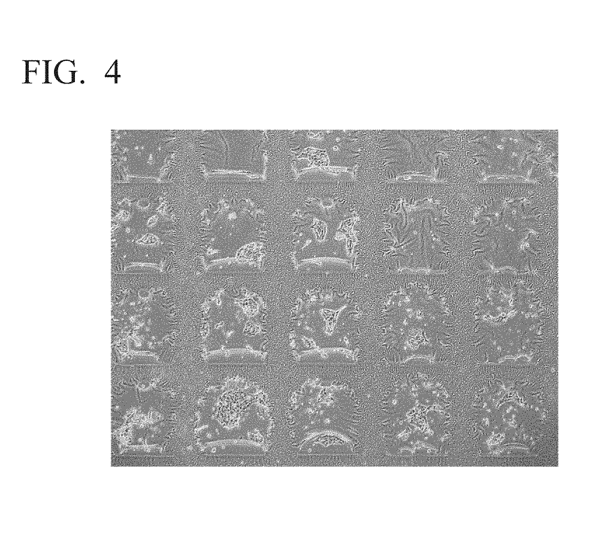

With respect to a substrate having a large number of pocket-like structures composed of crosslinked polymer formed in Example 2 on the surface thereof, cells were introduced into the pocket structure by repeatedly pouring the cell dispersion of MDCK cells, a cell line derived from canine renal tubule epithelial cells, or HepG2 cells, a cell line derived from human liver cancer, dispersed in a medium from the inlet direction of the pocket. The cells were cultured in an incubator as they were. FIG. 4 is a photograph showing the results of optical microscopic observation of the MDCK cells cultured in the present Example. As a result, it was confirmed that the cells were stably retained and survived in the pocket structure even after the next day.

### Example4

### Cell Separation Using Pocket Structure

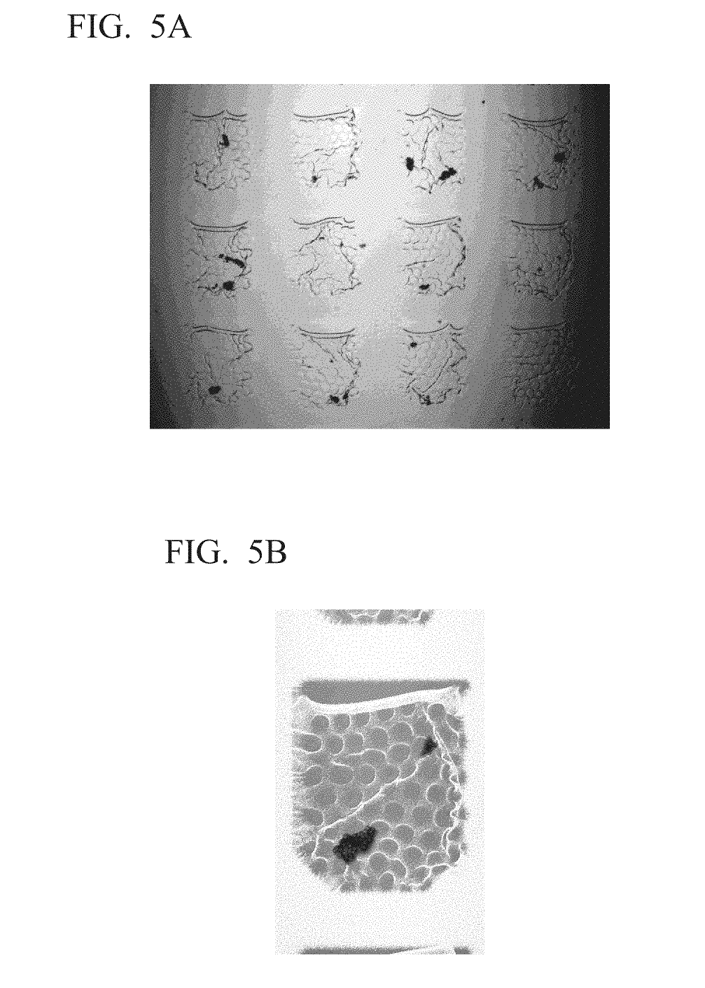

With respect to a substrate having a large number of mesh-like pocket structures formed in Example 2 on the surface thereof, a cell mass was introduced into the pocket structure by repeatedly pouring the cell dispersion containing the cell mass of human iPS cells having a distribution in size from the inlet direction of the pocket. Furthermore, it was confirmed that only the cell mass larger than the mesh structure of the pocket can be left inside the pocket structure by tilting the substrate with the inlet direction of the pocket facing upward and pouring the medium from the pocket inlet direction. The cells were cultured in an incubator as they were. FIGS. 5A and 5B are photographs showing the results of optical microscopic observation of the cell mass of human iPS cells cultured in the present Example. As a result, it was confirmed that the cells were stably retained and survived in the pocket structure even after the next day.

### Example 5

### Preparation of Structure Composed of Crosslinked Polymer for Cell Culture

pPAGMMA containing a photoacid generating residue and having a monomer fraction of 2 mol % was used as a photo-dissoluble polymer having a photoacid generating ability. First, a trifluoroethanol solution containing 0.5 mass % of pPAGMMA was spin-coated on a polystyrene substrate and heated at 85° C. for 1 hour.

Subsequently, a methanol solution containing 0.1 mass % of hydroxypropylcellulose, 0.001 mass % of TMMGU, and 0.002 mass % of sulfuric acid was prepared as a composition containing a crosslinking agent capable of crosslinking by the action of an acid and a crosslinkable polymer. The composition was spin-coated on the substrate and heated at 85° C. for 5 minutes.

This was followed by exposure of the entire surface of the substrate to light having a wavelength of 436 nm at an irradiation dose of 3 J/cm². Subsequently, the substrate was heated at 85° C. for 2 hours. As a result, a polymer sheet was formed on the entire surface of the substrate.

Subsequently, the formed polymer sheet was exposed to light having a wavelength of 436 nm at an irradiation dose of 10 J/cm2 in a patternwise manner in ethanol containing 20 weight % of water to dissolve pPAGMMA, and the polymer sheet was locally peeled off from the substrate surface. Subsequently, the substrate surface was intensively washed with water, whereby the peeled polymer sheet was broken and removed in a patternwise manner.

In this manner, the structure composed of crosslinked polymer for cell culture having a cell adhesivable portion and a non-cell adhesivable portion was obtained. Here, the region from which the polymer sheet has been removed is the cell adhesivable portion, and the portion where the polymer sheet is present is the non-cell adhesivable portion.

MDCK cells, NIH/3T3 cells, a mouse fetus-derived fibroblast cell line, or human iPS cells were seeded on the resulting structure composed of crosslinked polymer for cell culture and cultured until the next day. In the culture of human iPS cells, the surface of the structure composed of crosslinked polymer for cell culture was coated with Matrigel (manufactured by Corning Incorporated).

As a result, in any of the cells, the cells adhered only to the region from which the polymer sheet was removed (the cell adhesivable portion), and therefore the cells could be cultured in a patternwise manner. In addition, the cell adhesion inhibition of the region where the polymer sheet is present (non-cell adhesivable portion) was very high, and the cells grown to overconfluence by continuous culture for another 2 days also did not protrude from the non-cell adhesivable portion.

FIG. 6 is a photograph showing the results of optical microscopic observation of the MDCK cells cultured in the present Example. In the case where the cells were detached in this state, the cells in each of the island-like cell adhesivable portions formed one cell mass each, and therefore a cell mass having a uniform size could be obtained.

FIGS. 7A and 7B are photographs showing the results of optical microscopic observation of the NIH/3T3 cells cultured in the present Example. In the structure composed of crosslinked polymer for cell culture shown in FIG. 7A, the cell adhesivable portion and the non-cell adhesivable portion were linearly arranged in parallel with each other. As a result, it was possible to align and orient the cells in parallel. Further, in the case where the cells in FIG. 7B were detached, the cells in each of the island-like cell adhesivable portions formed one cell mass each, and therefore a cell mass having a uniform size could be obtained.

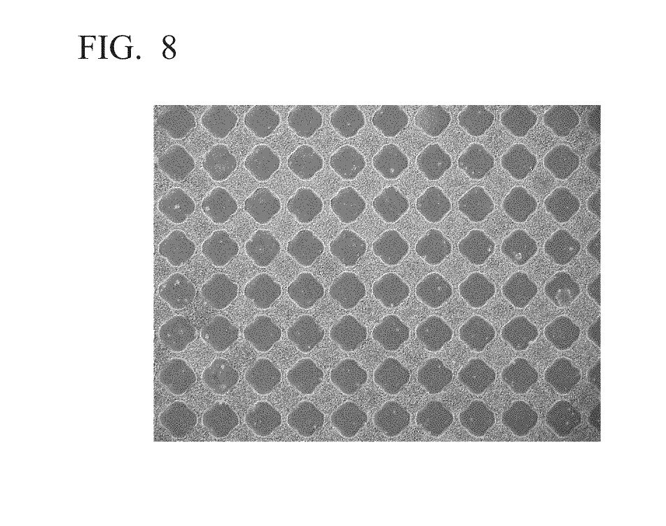

FIG. 8 is a photograph showing the results of optical microscopic observation of the human iPS cells cultured in the present Example. As a result, it was confirmed that the human iPS cells can also be cultured in a patternwise manner. Further, in the case where the cells in FIG. 8 were detached, the cells in each of the island-like cell adhesivable portions formed one cell mass each, and therefore a cell mass having a uniform size could be obtained.

### INDUSTRIAL APPLICABILITY

According to the present invention, it is possible to provide a novel microstructure forming technique. More specifically, the present invention is capable of providing a method for producing a structure composed of crosslinked polymer, a laminate for producing a structure composed of crosslinked polymer, a structure composed of crosslinked polymer, a structure composed of crosslinked polymer for cell culture, a cell culture method, a method for producing a cell mass, and a cell mass.

### REFERENCE SIGNS LIST

10: substrate

20: photo-dissoluble polymer layer having a photoacid generating ability

30: pregel composition

31: crosslinked polymer sheet

40: solvent (liquid)

1. A method for producing a structure composed of crosslinked polymer, comprising:
laminating a photo-dissoluble polymer layer on a substrate;
laminating a layer containing a crosslinkable polymer on the photo-dissoluble polymer layer;
irradiating the layer containing the crosslinkable polymer with light in a first patternwise manner under crosslinking conditions to crosslink the crosslinkable polymer in the first patternwise manner to obtain a crosslinked polymer sheet;
washing and removing a uncrosslinked crosslinkable polymer to obtain a crosslinked polymer sheet patterned in the first patternwise manner; and
irradiating the photo-dissoluble polymer layer with light in a second patternwise manner under dissolution conditions to dissolve the photo-dissoluble polymer layer in the second patternwise manner, and peeling the crosslinked polymer sheet from the substrate.

2. The method for producing the structure composed of crosslinked polymer according to claim 1, further comprising:
breaking and removing the crosslinked polymer sheet peeled from the substrate.

3. The method for producing the structure composed of crosslinked polymer according to claim 1,
wherein the crosslinkable polymer is a compound having a plurality of hydroxyl groups and having a weight-average molecular weight of 2,000 or more.

4. The method for producing the structure composed of crosslinked polymer according to claim 1,
wherein the crosslinkable polymer is water-soluble.

5. The method for producing the structure composed of crosslinked polymer according to claim 1,
wherein the crosslinkable polymer is a polysaccharide or a derivative thereof.

6. (canceled)

7. A structure composed of crosslinked polymer, comprising:
a substrate;
a photo-dissoluble polymer layer laminated on the substrate and patterned in a reversed pattern of a second patternwise manner; and
a crosslinked polymer sheet, at least one portion thereof is laminated on the photo-dissoluble polymer layer,
wherein the crosslinked polymer sheet is patterned in a first patternwise manner and peeled from the substrate in the second patternwise manner.

8. The structure composed of crosslinked polymer according to claim 7, wherein a peeled portion of the crosslinked polymer sheet is removed and the substrate is exposed at the peeled portion and the exposed part of the substrate forms a cell adhesivable portion, and the remaining crosslinked polymer sheet forms a non-cell adhesivable portion.

9. The structure composed of crosslinked polymer according to claim 8,
wherein the cell adhesivable portion and the non-cell adhesivable portion are linearly arranged in parallel with each other.

10. The structure composed of crosslinked polymer according to claim 8,
wherein the cell adhesivable portion has a plurality of island-like portions and connecting portions for connecting together the plurality of the island-like portions.

11. The structure composed of crosslinked polymer according to claim 10,
wherein all of the island-like portions have substantially the same area.

12. A cell culturing method for uniformly culturing cells, comprising:
a step of culturing cells on the surface of the structure composed of crosslinked polymer according to claim 11, with the cells being adhered to the plurality of the island-like portions.

13. A method for producing a cell mass, comprising:
a step of culturing cells on the surface of the structure composed of crosslinked polymer according to claim 11; and
a step of detaching the cells to obtain substantially the same number of cell masses as the number of the island-like portions consisting of the cells being adhered to the plurality of the island-like portions.

14. (canceled)
